(19) United States
(12) Patent Application Publication
(10) Pub. No.: US 2013/0089944 A1
(43) Pub. Date: Apr. 11, 2013

(54) SOLAR CELL SILICON WAFER PROCESS

(71) Applicant: Jihyo M. Rhieu, Mesa, AZ (US)

(72) Inventor: Jihyo M. Rhieu, Mesa, AZ (US)

(73) Assignee: AMTECH SYSTEMS, INC., Tempe, AZ (US)

(21) Appl. No.: 13/703,431

(22) PCT Filed: Jun. 9, 2011
(86) PCT No.: PCT/US11/39734

§ 371 Date: Dec. 11, 2012

Related U.S. Application Data
(60) Provisional application No. 61/353,742, filed on Jun. 11, 2010.

(51) Int. Cl. H01L 31/18

(52) U.S. Cl. CPC H01L 31/186
USPC 438/72; 438/57

(57) ABSTRACT

In the production of silicon solar cells wherein the process includes a dopant diffusion to form a pn junction, a back surface field layer, or a front surface field layer, resulting in the formation of a doped glass surface, a HF vapor etch is utilized to remove the doped glass layer and expose the wafer surface. The exposed surface is subjected to an oxygen treatment for predetermined times and temperatures to alter the surface state. The HF vapor etch followed by the oxygen treatment, or chemical oxidation, results in significant improvement in solar cell electrical properties.

### CROSS-REFERENCE TO RELATED APPLICATION

This application is related to and claims priority to a provisional application entitled “SOLAR CELL SILICON WAFER PROCESS” filed Jun. 11, 2010, and assigned Ser. No. 61/353,742.

### FIELD OF THE INVENTION

The present invention relates to processes for the production of silicon solar cells and more particularly to an improvement in the method of production by the HF vapor removal of doped glass from the silicon wafer surface and subsequent oxygen treatment.

### BACKGROUND

A typical prior art process for the production of crystalline silicon cells includes the wafer splitting of appropriately doped stacked silicon wafers followed by SDR (saw damage removal) and surface texturing of the wafer to remove saw damages and reduce reflectivity of the wafer's surface. In the case ofp-type silicon cells homogenous n+ diffusion (such as phosphorous diffusion) forms an emitter; this diffusion results in the formation of a PSG (phosphosilicate glass) layer on the wafer surface. This PSG layer is subsequently removed by a wet HF process wherein the wafer with the PSG surface is subjected to a wet dip process. The process typically includes dipping the surface into diluted wet HF. It is important at this time to minimize the time between the HF dip and the subsequent deposition of an antireflection coating to avoid undesirable growth of native oxide and contamination on the wafer surface. Further, the wet dip process requires appropriate rinsing and drying steps to prepare the resulting surfaces for the application of the antireflection coating. This coating is typically a silicon nitride (SiN) which may be applied using plasma enhanced chemical vapor deposition (PECVD) techniques. This antireflection coating (AR) permits the admission of light energy and reduces reflection that is otherwise inherent in the surface properties of the wafer. The AR coating layer may also improve the electrical properties of the cell by surface passivation.

Printing techniques are then typically used to form BSF (back surface field) and to provide contacts to the wafer surfaces; usually an aluminum layer is printed on the rear of the cell and dried. Subsequent printing on the rear of the cell may also provide solderable contacts. Screen printing techniques may be used for providing appropriate contacts for the front of the cell to provide appropriate electrical contact while minimizing the blocking of solar energy striking the cell. The screen printed layers are fired to form BSF and good contacts. The resulting cell may then be subjected to edge isolation using one of several available well known techniques.

Efficiencies of the resulting solar cell are critical to the utilization of cells in commercial applications. Further, the economies of production dictate that the processes used for the production of such cells be compatible with manufacturing techniques required for high volume production. The increase in either or both the efficiency of the cell and the increased throughput of the manufacturing process are significant in the manufacture and use of solar cells.

### SUMMARY OF THE INVENTION

It has been found that the substitution of an HF vapor PSG removal process for the typical wet HF process combined with oxygen treatment of the resulting PSG free surface results in significant improvement in the resulting solar cell electrical properties including efficiencies and can reduce the use of environmentally hazardous materials for the production of solar cells. For both multicrystalline wafers and mono crystalline wafers the combination of HF vapor PSG removal process and low temperature oxygen treatment (below 600° C.) may be used, but the combination of HF vapor PSG removal process and high temperature oxygen treatment (700-1000° C.) may also be used to further improve the resulting electrical properties for monocrystalline wafer processing.

### BRIEF DESCRIPTION OF THE DRAWINGS

The present invention may more readily be described by reference to the accompanying drawings in which:

FIG. 1 is a flow chart illustrating a process incorporating the teachings of the present invention.

FIG. 2 is a schematic representation of apparatus suitable for implementing the dry HF process of the present invention.

FIG. 3 is a schematic representation of suitable apparatus for implementing the oxygen treatment of the wafer surfaces in accordance with the teachings of the present invention.

FIG. 4 is a schematic representation of suitable apparatus showing the use of a PECVD machine for implementing the oxygen treatment of the wafer surfaces in accordance with the teachings of the present invention.

FIG. 5 is a schematic representation of suitable apparatus showing the use of an oxidation furnace for implementing the oxygen treatment of the wafer surfaces in accordance with the teachings of the present invention.

FIG. 6 is a bar graph showing the results of sample tests indicating the advantages achieved by the present invention.

### DETAILED DESCRIPTION OF THE INVENTION

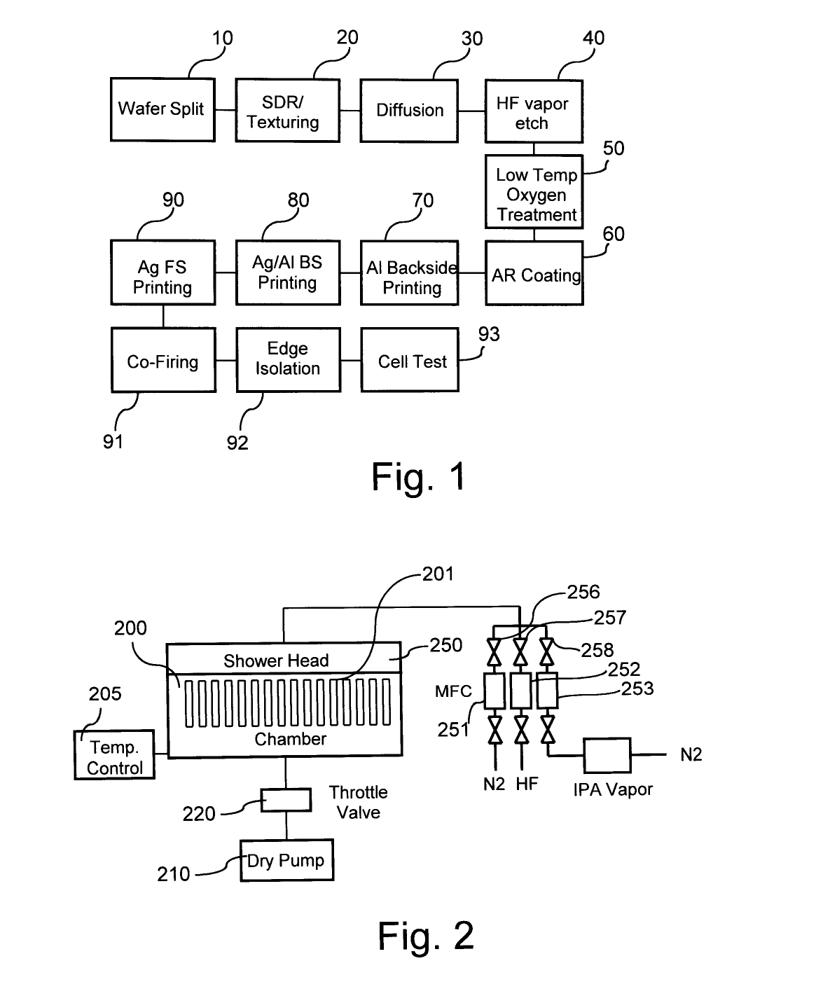

Referring to FIG. 1, a flow chart illustrating a process incorporating the teachings of the present invention for the production of crystalline silicon cells is shown.

Referring to FIG. 1, multicrystalline silicon wafers are provided 10 and may be obtained using any of several known wafer production techniques including sawing cast silicon ingots. Monocrystalline silicon wafers may be used by slightly modifying the process steps. The silicon wafers are lightly p doped. The wafers are then subjected to saw damage removal and texturing 20 in a well known manner of the wet chemical dip and/or other dry processes and then submitted to a diffusion step 30 for the formation of the appropriate pn junction. The diffusion 30, a phosphorous diffusion for the p doped wafer, creates a phosphosilicate glass (PSG) on the wafer surface; this PSG surface must be removed before further processing. Accordingly, the wafers are then subjected to a HF vapor etching process 40, to be described more fully hereinafter, for the removal of the PSG surface and to expose the underlying surface of the wafer. The wafers are then subjected to a low temperature oxygen treatment 50, to be described more fully hereinafter, and then subjected to a plasma enhanced chemical vapor deposition of a hydrogenated silicon nitride layer 60 to form an antireflection coating. The silicon nitride layer formed in this step is used as a passivation layer as well as an effective antireflective coating on the silicon solar cell wafer. The solar cell may then be subjected to known techniques for the application of back surface field (BSF), contacts and grids, such as using aluminum, aluminum/silver, and silver printing techniques 70, 80 and 90. The printed wafers may then be fired 91 and subjected to edge isolation 92 and subsequently made available for testing 93.

The above process flow is a sample of process flows currently used in the industry with the exception of the HF vapor etching 40 and the low temperature oxygen treatment 50. The remaining process steps may be modified by users; for example, when performing with isolation, a wet isolation step may be implemented after the p diffusion 30.

The same process may be followed when the silicon wafers are lightly n doped and a boron diffusion, for example, is used to form the pn junction. In this case, a boron diffusion for the n doped wafer creates a borosilicate glass (BSG) on the wafer surface; this BSG surface must be removed before further processing. Accordingly, the wafers are then subjected to a HF vapor etching process for the removal of the BSG surface and to expose the underlying surface of the wafer. The wafers are then subjected to oxygen treatment. If either a back surface field (BSF) or front surface field (FSF) layer is employed, the oxygen treatment is applied before forming the BSF or FSF layer and the SiN antireflection coating. When phosphorus diffusion is used for BSF or FSF formation, HF vapor PSG removal and oxygen treatment may be applied again before plasma enhanced chemical vapor deposition of a hydrogenated silicon nitride layer to form an antireflection coating. The order of emitter diffusion and formation of BSF or FSF can be changed.

When used with monocrystalline silicon wafers, the process may be modified slightly by increasing the oxygen treatment temperature up to approximately 1000° C. The HF vapor process step remains the same and the wafers are subjected to this oxygen treatment at a higher temperature.

The utilization of the HF vapor etch process for the removal of the doped glass (PSG or BSG for example) created on the wafer surface during the diffusion step, followed by an oxygen treatment prior to the deposition of the antireflection coating has been found to result in a significant improvement in the electrical properties including the efficiency of the resulting solar cell.

Referring to FIG. 2, a schematic representation of apparatus suitable for implementing the dry HF step of the process of the present invention is shown. A plurality of silicon wafers are placed within chamber 200 provided with boats onto which the wafers may be mounted. The wafers 201, having the doped glass film (PSG or BSG) generated during the previous diffusion step, are secured within the chamber while the temperature is selected in accordance with temperature controller 205, normally in the range of 50° C. to 250° C. The temperature can be controlled using conventional heat sources such as plate or coil heaters or lamps, etc. The pressure within the chamber is adjusted through utilization of the pump 210 through throttle valve 220 to provide a pressure within the chamber of 10 to 550 Torr. A showerhead 250 directs nitrogen, HF gas and isopropyl alcohol (IPA) through mass flow controllers 251, 252 and 253 and suitable valves 256, 257 and 258.

insure the uniformity of the PSG etching, it is desirable that the showerhead 250 is arranged to uniformly inject the gas for etching each wafer.

The following table is a sample implementation of the HF step in the process of the present invention. The table indicates the respective steps that may be used for evacuation of the chamber, N₂ purging, application of the HF for etching followed by the subsequent purging with N₂ and an IPA rinse.

| | | Time | Temper- | Pres- | Gas | | |
|---|---|---|---|---|---|---|---|
| | | | ature | sure | HF | N₂ | IPA |
| Step | Step Name | (sec) | (° C.) | (Torr) | (slm) | (slm) | (slm) |
| 1 | Pumping | 30 | 180 | — | 0 | 0 | 0 |
| 2 | N₂ Purge | 30 | 180 | 1 | 20 | 2 | 0 |
| 3 | Pumping | 60 | 180 | — | 0 | 0 | 0 |
| 4 | Etching | 120 | 180 | 160 | 30 | 0 | 0 |
| 5 | N₂ Purge | 30 | 180 | 1 | 20 | 2 | 0 |
| 6 | IPA Rinsing | 60 | 180 | 1 | 20 | 5 | 0.5 |
| 7 | N₂ Purge | 30 | 180 | 1 | 20 | 2 | 0 |
| 8 | Pumping | 30 | 180 | — | 0 | 0 | 0 |
| 9 | N₂ Purge | 30 | 180 | 1 | 20 | 2 | 0 |

It may be noted that the above table could be modified if IPA or water (H₂O) vapor is desired with HF vapor for the etching step.

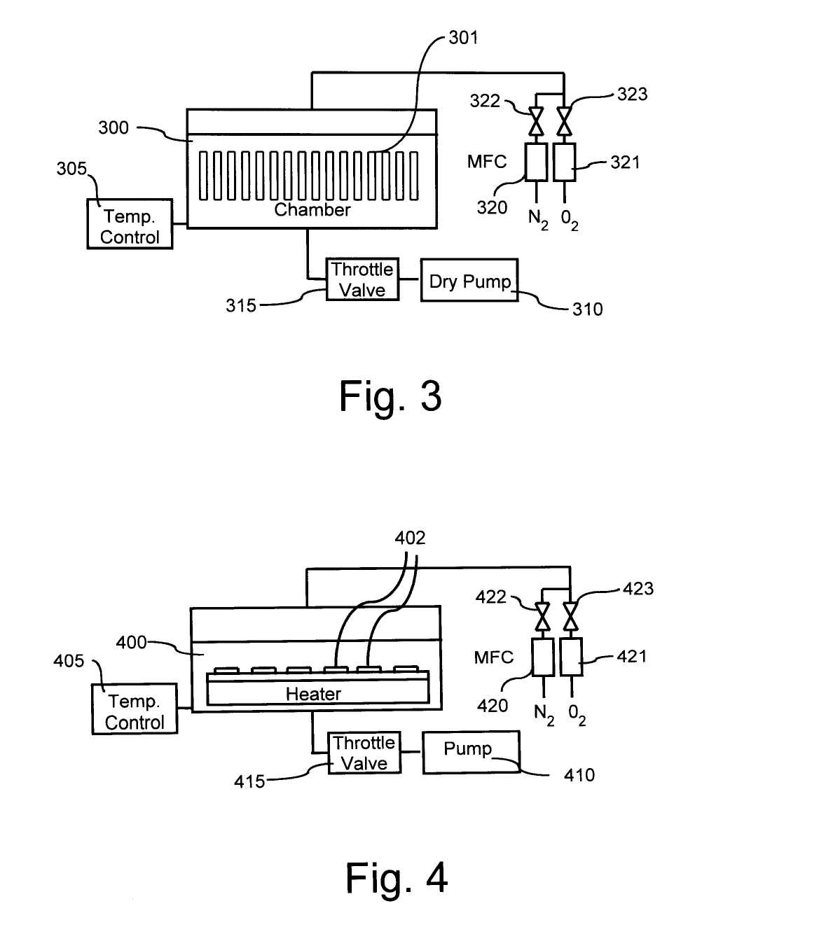

Referring to FIG. 3, a schematic representation of one form of a suitable apparatus for implementing the oxygen treatment of the wafer surfaces is shown. A chamber 300 is provided having suitable chucks for the mounting of wafers, whose surfaces are to be treated. The chamber is provided with temperature controls 305 for maintaining the temperature of the chamber in the range of 200° C. to 600° C., preferably 350° to 500° C. A pump 310 is provided acting through throttle valve 315 to maintain suitable pressure within the chamber while sources of oxygen and nitrogen are connected through mass flow controllers 320, 321 and valves 322, 323, respectively, to the chamber. The pressure may be selected from 1 to 760 Torr and preferably between 5 to 100 Torr. The oxygen surface treatment extends for 1 to 30 minutes and preferably 1½ to 5 minutes. Typically lower temperatures require longer processing time.

When using monocrystalline silicon wafers the process may be slightly modified. The combination of the HF vapor doped glass removal and low temperature oxygen treatment (200-600° C.) may still be used, but to further improve the cell performances we may use a combination of the HF vapor doped glass removal and high temperature oxygen treatment (700-1000° C.) instead of the aforementioned HF vapor doped glass removal and low temperature oxygen treatment (200-600° C.) combination. The high temperature oxidation usually provides oxide having better oxide quality and lower surface state, which result in further improvement in solar cell electrical properties. However, the high temperature treatment may not be appropriate for multicrystalline wafer processing.

It may be noted that the apparatus of FIG. 3 may be similar to the apparatus described in connection with FIG. 2. The chamber such as that shown at 200 in FIG. 2 may be used for the dry HF doped glass removal as well as the subsequent oxygen treatment. The pressures and the temperatures as well as the selection of gas, may be determined to permit doped glass removal, then immediately follow within the same chamber with the selection of the appropriate temperature and pressure within that chamber and the selection of the oxygen for oxygen treatment; thus, no vacuum break is necessary and the handling of the wafers is minimized while the apparatus required for doped glass removal and subsequent oxygen treatment may be the same apparatus. However, it may be more effective to use a separate a chamber for the oxygen treatment to avoid temperature ramp up/down time. In this case, the oxygen treatment chamber may be a conventional oven and it may be located closely to the HF vapor etching chamber.

The oxygen treatment may be accomplished utilizing a commercially available wafer processing apparatus for implementing plasma enhanced chemical vapor deposition (PECVD) for multicrystalline wafers. Referring to FIG. 4, a schematic representation of the chamber, which is a part of PECVD processing apparatus, is shown for implementing the oxygen treatment of the wafer surfaces. A chamber 400 is provided for supporting a plurality of wafers 402. The chamber 400 is provided with temperature controls 405 for maintaining the temperature of the chamber in the range of 200° C. to 600° C., preferably 350° C. to 600° C. A pump 410 is provided acting through throttle valve 415 to maintain a suitable pressure within the chamber while sources of oxygen and nitrogen are connected through mass flow controllers 420, 421 and valves 422, 423, respectively, to the chamber. The chamber is supplied with oxygen or a mixture of nitrogen and oxygen for a period of 1 to 30 minutes and preferably 1½ to 5 minutes. The nitrogen/oxygen ratio is 0 to 10 parts nitrogen to 1 part oxygen. Then the wafers having had the oxygen treatment to the exposed surfaces may proceed to a typical SiN PECVD coating process either in the same chamber or by being removed to an appropriate chamber for application of an antireflection and passivation layer.

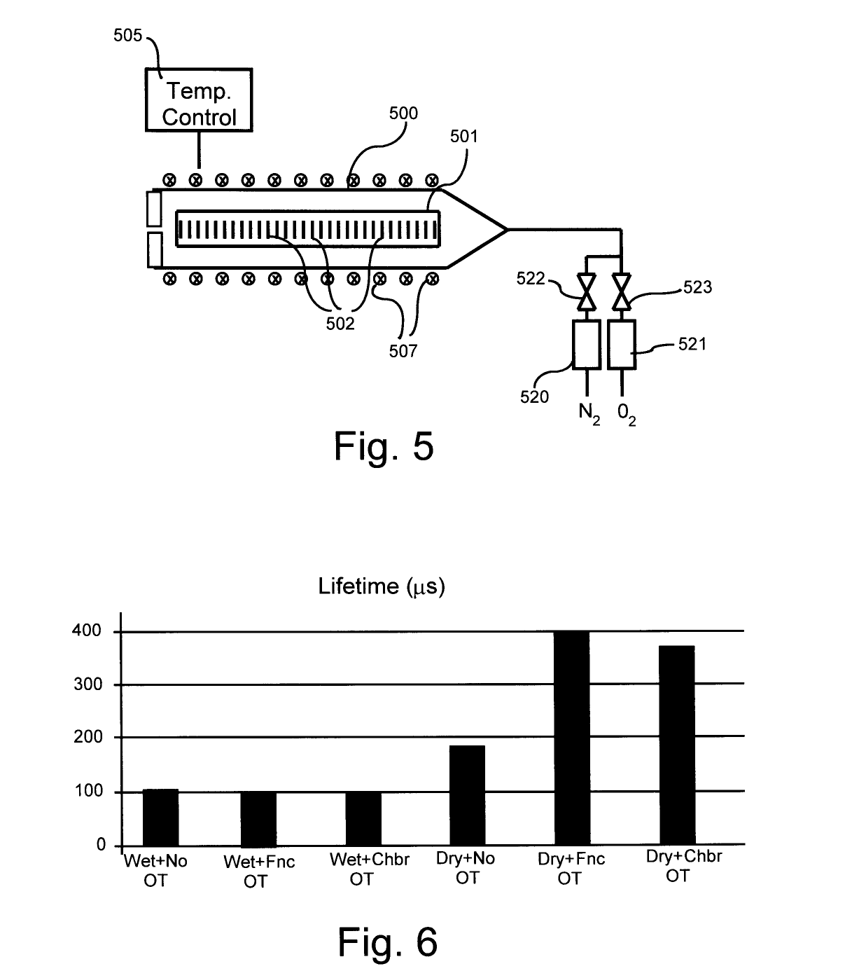

The oxygen treatment may also be accomplished utilizing a conventional oven or a diffusion furnace. Referring to FIG. 5, a schematic representation of the diffusion furnace apparatus is shown for implementing the oxygen treatment of the wafer surfaces. A chamber 500 is provided for supporting quartz tubes 501 having a plurality of wafers 502. The chamber 500 is surrounded with heater coils 507 connected to temperature controls 505 for maintaining the temperature of the chamber in the range of 200° C. to 600° C., preferably 350° C. to 500° C. for multicrystalline wafers and in the range of 200° C. to 1000° C. for monocrystalline wafers. Oxygen and nitrogen lines are connected through mass flow controllers 520, 521 and valves 522, 523, respectively, to the chamber. The chamber is supplied with oxygen or a mixture of nitrogen and oxygen for a period of 1 to 30 minutes and preferably 1½ to 5 minutes. When the nitrogen/oxygen mixture is used, the mixture may be in the range of 0 to 20 parts nitrogen to 1 part oxygen. The wafers having had the oxygen treatment to the exposed surfaces may then be removed to an appropriate chamber for the application of the AR coating. This latter step may occur in a PECVD chamber to apply a SiN layer.

The oxygen treatment is basically one kind of oxidation. The treatment may also be accomplished utilizing chemical oxidation. An example of chemical oxidation is nitric acid oxidation of silicon (NAOS). Immersing the silicon wafer surfaces in nitric acid (HNO₃) solution forms ultrathin silicon dioxide (SiO₂). The exposed wafer surface may be immersed in 20 to 100 wt %, and preferably 50 to 80 wt % nitric acid, for 1 to 30 minutes and preferably 5 to 10 minutes. Typical oxide thickness from the chemical oxidation is approximately 1.3 nm to 1.5 nm. The temperature of nitric acid solution from room temperature up to its boiling temperature corresponding to the concentration of the solution and preferably 70° C. to the boiling temperature may be used. It is known that the chemical oxide formed with 68 wt % nitric acid solution provides much lower leakage current characteristic than that formed with 61 wt % nitric acid solution at its boiling temperature of 113° C. Since the NAOS is a self-limiting process, processing time is not very critical. The HF vapor etching and the chemical oxidation also work for improvement of solar cell electrical properties including cell efficiency. The wafers having had the oxygen treatment to the exposed surfaces may then be removed to an appropriate chamber to the application of the AR coating. This latter step may occur in a PECVD chamber to apply a SiN layer.

### Example 1

A number of wafers, 48 wafers in the current example, formed of lightly p doped silicon were subjected to a phosphorous diffusion resulting in a PSG layer; the wafers were mounted on the cart in a PECVD chamber. The chamber was pumped to the base pressure of approximately 10 mTorr and then the chamber pressure was controlled to 100 Torr. The heater temperature was adjusted to approximately 120° C. The wafer surfaces were then etched for a period of 90 seconds with HF gas with IPA vapor. The chamber was purged and then pumped. The chamber was purged again and then the temperature of the chamber was raised to 350° C. while the pressure within the chamber was adjusted to 100 Torr. Oxygen was then admitted to the chamber through the showerheads and the chamber with the oxygen atmosphere at the temperature of 350° C. was maintained for 2 minutes. An AR coating was then applied using typical PECVD parameters. It was found that solar cells produced in accordance with this modified process exhibited significant improvement in solar cell electrical properties including cell efficiency.

### Example 2

Typically four boats with 50 wafers per boat, (a total of 200 wafers) formed of lightly p doped silicon were subjected to a phosphorous diffusion resulting in a PSG layer; the boats were transferred to an HF vapor etching chamber. The chamber was pumped to the base pressure of 10 mTorr and then the chamber pressure was controlled to 160 Torr. The heater temperature was adjusted to approximately 150° C. The wafer surfaces were then etched for a period of 120 seconds with HF gas with water vapor. The chamber was pumped and purged. The chamber was pumped again and then the chamber was back filled. The boats were removed from the HF vapor chamber and then transferred into the furnace. In the furnace the temperature was controlled at 350° C. When the temperature stabilized, oxygen was introduced with nitrogen to the furnace and the temperature of 350° C. was maintained for 5 minutes. The wafers were then loaded on the PECVD cart and the cart moved into the PECVD chamber. An AR coating was applied using typical PECVD parameters. This modified process also exhibited significant improvement in solar cell electrical properties including cell efficiency.

Referring now to FIG. 6, results of sample tests are shown indicating some of the advantages achieved by the present invention through the utilization of HF vapor etching and oxygen treatment. For these test p-type double-side polished float zone (FZ) wafers were used and light phosphorus diffusion (target Rs: 195 ohm/sq.) was performed. Diffusion test runs were divided into wet HF PSG removal and dry HF vapor PSG removal each followed by another division into tests for no oxygen treatment (reference group), 500° C. 5 min furnace oxygen treatment and 500° C. 5 min PECVD chamber oxygen treatment. Approximately 85 nm thick SiN layers were then deposited on both sides of the wafers using a PECVD machine. Finally, carrier lifetime measurement was performed before and after firing.

FIG. 6 shows data for these divided groups after firing. Here the wet etch with no oxygen treatment is a reference group corresponding to the prior art. The lifetime data for wet etch and oxygen treatment, whether treatment was by furnace or PECVD, show no improvement compared to the reference group. Applying the dry HF vapor etch and no oxygen treatment resulted in small improvement in lifetime property. In contrast, the groups using the dry HF vapor etch and the oxygen treatment show significant further improvement in carrier lifetime regardless of oxygen treatment method, furnace treatment or PECVD chamber treatment.

The similar results were achieved when using HF vapor etch and chemical oxidation (NAOS method).

The present invention has been described in terms of selected specific embodiments of the method incorporating details to facilitate the understanding of the principles and operation of the invention. Such reference herein to a specific embodiment and details thereof is not intended to limit the scope of the claims appended hereto. It will be apparent to those skilled in the art that modifications may be made in the methods and embodiments chosen for description without departing from the spirit and scope of the invention.

What is claimed:

1. In a process for manufacturing silicon solar cells wherein lightly doped silicon wafers are subjected to a diffusion step to form a pn junction, a BSF layer, or a FSF layer, and wherein a doped glass coating is formed on the wafer surface as a result of the diffusion step, the improvement comprising:
(a) dry etching the doped glass coating with HF vapor to remove the coating and expose the wafer surface; and
(b) treating the exposed wafer surface by subjecting the exposed surface to oxygen for a predetermined time at a predetermined temperature to improve the solar cell electrical properties.

2. The process of claim 1 wherein the diffusion step is a phosphorous diffusion step and said doped glass coating is a PSG coating.

3. The process of claim 1 wherein the diffusion step is a boron diffusion step and said doped glass coating is a BSG coating.

4. The process of claim 1 wherein the dry etching with HF vapor is conducted at a temperature of 50° C. to 250° C.

5. The process of claim 4 wherein the dry etching with HF vapor is conducted at a pressure of 10 to 550 Torr.

6. The process of claim 1 wherein the dry etching is conducted with HF vapor and IPA.

7. The process of claim 1 wherein the dry etching is conducted with HF vapor and water vapor.

8. The process of claim 1 wherein said treating the exposed wafer surface by subjecting the exposed surface to O₂ is conducted at a pressure 5 Torr to 1 atm.

9. The process of claim 1 wherein said predetermined temperature is 200° C. to 600° C. and preferably 350° C. to 500° C. for multicrystalline wafers.

10. The process of claim 1 wherein said predetermined temperature is 200° C. to 1000° C. and preferably 500° C. to 850° C. for monocrystalline wafers.

11. The process of claim 1 wherein said predetermined time is 1 to 30 minutes and preferably 1½ to 5 minutes.

12. In a process for manufacturing silicon solar cells wherein lightly doped silicon wafers are subjected to a diffusion step to form a pn junction, a BSF layer, or a FSF layer, and wherein a doped glass coating is formed on the wafer surface as a result of the diffusion step, the improvement comprising:
(a) dry etching the doped glass coating with HF vapor to remove the coating and expose the wafer surface; and
(b) treating the exposed wafer surface by subjecting the exposed surface to a nitric acid solution.

13. The process of claim 12 wherein the dry etching with HF vapor is conducted at a temperature of 50° C. to 250° C.

14. The process of claim 13 wherein the dry etching with HF vapor is conducted at a pressure of 10 to 550 Torr.

15. The process of claim 12 wherein the dry etching is conducted with HF vapor and IPA.

16. The process of claim 12 wherein the dry etching is conducted with HF vapor and water vapor.

17. The process of claim 12 wherein said treating of the exposed wafer surface is by immersing the exposed surface in 20 to 100 wt % nitric acid solution and preferably 50 to 80 wt % nitric acid solution

18. The process of claim 12 wherein said treating of the exposed wafer surface is by immersing the exposed surface in nitric acid solution at room temperature to boiling temperature corresponding to the concentration of the solution and preferably 70° C. to the boiling temperature.

19. The process of claim 12 wherein said treating of the exposed wafer surface is by immersing the exposed surface in nitric acid solution for 1 to 30 minutes and preferably 5 to 10 minutes.

20. A process for producing the silicon solar cells having electrical properties comprising:
(a) providing a lightly doped silicon wafer;
(b) subjecting the wafer to diffusion to produce a pn junction, a BSF layer or a FSF layer, and create a doped glass layer on the wafer surface;
(c) removing the doped glass layer by dry etching the layer with HF vapor to expose a wafer surface beneath the doped layer to expose the wafer surface;
(d) treating the exposed surface with O₂ at a predetermined temperature and for a predetermined time to improve the solar cell electrical properties; and
(e) applying an antireflection coating to said surface.

21. The process of claim 20 wherein the dry etching with HF vapor is conducted at a temperature of 50° C. to 250° C.

22. The process of claim 21 wherein the dry etching with HF vapor is conducted at a pressure of 10 to 550 Torr.

23. The process of claim 20 wherein the dry etching with HF is conducted with IPA.

24. The process of claim 20 wherein the dry etching is conducted with HF vapor and water vapor.

25. The process of claim 20 wherein said treating the exposed wafer surface by subjecting the exposed surface to O₂ is conducted at a pressure 5 Torr to 1 atm.

26. The process of claim 20 wherein said predetermined temperature is 200° C. to 600° C. and preferably 350° C. to 500° C. for multicrystalline wafers.

27. The process of claim 20 wherein said predetermined temperature is 200° C. to 1000° C. and preferably 500° C. to 850° C. for monocrystalline wafers.

28. The process of claim 20 wherein said predetermined time is 1 to 30 minutes and preferably 1½ to 5 minutes.
